(19) United States
(12) Patent Application Publication
(10) Pub. No.: US 2026/0181772 A1
(43) Pub. Date: Jun. 25, 2026

(54) COMPOSITE CERAMIC SUBSTRATE AND METHOD FOR PRODUCING THE SAME

(71) Applicant: TONG HSING ELECTRONIC INDUSTRIES, LTD., Taoyuan City (TW)

(72) Inventors: CHIH-WEI MAO, Taoyuan City (TW); TSUNG-YING CHANG, Taoyuan City (TW); CHUNG-HO WEI, Taoyuan City (TW); MING-YI HSU, Taoyuan City (TW); CHI-WEN HUANG, Taoyuan City (TW)

(21) Appl. No.: 19/463,111

(22) Filed: Jan. 29, 2026

Related U.S. Application Data
(63) Continuation-in-part of application No. 18/964,701, filed on Dec. 2, 2024.

(30) Foreign Application Priority Data
Aug. 29, 2024 (TW) 113132469
Dec. 12, 2025 (TW) 114148784

(51) Int. Cl. H05K 1/09; H05K 1/02; H05K 3/46

(52) U.S. Cl. CPC H05K 1/09; H05K 1/0298; H05K 3/4602; H05K 2203/1131

(57) ABSTRACT

A composite ceramic substrate and method for producing the same. The composite ceramic substrate includes a ceramic substrate, a circuit board, and a composite adhered structure adhered to the ceramic substrate and the circuit board. The composite adhered structure includes a first active metal layer adhered to the ceramic substrate, a second active metal layer adhered to the circuit board, and a solder layer arranged between the first active metal layer and the second active metal layer. The first active metal layer includes titanium hydride. The second active metal layer includes tin, copper, and titanium hydride. The solder layer includes tin, copper, and titanium hydride.

### CROSS-REFERENCE TO RELATED PATENT APPLICATION

This application claims the benefit of priorities to Taiwan Patent Application No. 113132469, filed on Aug. 29, 2024 and No. 114148784, filed on Dec. 12, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a ceramic substrate and method for producing the same, and more particularly to a composite ceramic substrate and method for producing the same.

### BACKGROUND OF THE DISCLOSURE

In an active metal brazing (e.g., AMB) process of a conventional method for producing a ceramic substrate, a high content of silver is used. For example, silver accounts for more than 50 wt % or more than 70 wt % of a total weight of the ceramic substrate. However, the high content of silver brings about the probability of electromigration, and also causes the active metal brazing process to have a high cost.

### SUMMARY OF THE DISCLOSURE

In response to the above-referenced technical inadequacy, the present disclosure provides a composite ceramic substrate and method for producing the same, so as to effectively improve on the issues of the probability of electromigration and the high procedure cost resulting from the high content of silver used in a conventional method for producing a ceramic substrate.

In order to solve the above-mentioned problems, one of the technical aspects adopted by the present disclosure is to provide a composite ceramic substrate. The composite ceramic substrate includes a ceramic board, a circuit board, and a composite adhering structure adhered to the ceramic board and the circuit board. The composite adhering structure includes a first active metal layer, a second active metal layer, and a solder layer. The first active metal layer is adhered to the ceramic board. The first active metal layer includes titanium hydride. The second active metal layer is adhered to the circuit board. The second active metal layer includes tin, copper, and titanium hydride. The solder layer is arranged between the first active metal layer and the second active metal layer. The solder layer includes tin, copper, and titanium hydride.

In order to solve the above-mentioned problems, another one of the technical aspects adopted by the present disclosure is to provide a method for producing a composite ceramic substrate. The method includes a first printing process, a second printing process, an assembling process, and a sintering process. The first printing process is implemented by printing a first active metal layer onto a ceramic board and then printing a solder layer onto the first active metal layer. The first active metal layer includes titanium hydride. The solder layer includes tin, copper, and titanium hydride. The second printing process is implemented by printing a second active metal layer onto a circuit board. The second active metal layer includes tin, copper, and titanium hydride. The assembling process is implemented by assembling one side of the circuit board having the second active metal layer formed thereon to one side of the ceramic board having the first active metal layer and the solder layer formed thereon. The sintering process is implemented by sintering the circuit board, the first active metal layer, the second active metal layer, the solder layer, and the ceramic board, which are assembled to form a composite ceramic substrate.

Therefore, in the composite ceramic substrate and method for producing the same, by virtue of “the first active metal layer including titanium hydride, the solder layer including tin, copper, and titanium hydride, and the second active metal layer including tin, copper, and titanium hydride,” the issues of the probability of electromigration and the high cost due to the high content of silver used in a conventional method for producing a ceramic substrate can be effectively improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a composite ceramic substrate according to one embodiment of the present disclosure;

FIG. 2 is a schematic view of a composite ceramic substrate according to another embodiment of the present disclosure;

FIG. 3 is a flowchart of a method for producing a composite ceramic substrate according to one embodiment of the present disclosure; and

FIG. 4 is a flowchart of a method for producing a composite ceramic substrate according to another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [Composite Ceramic Substrate]

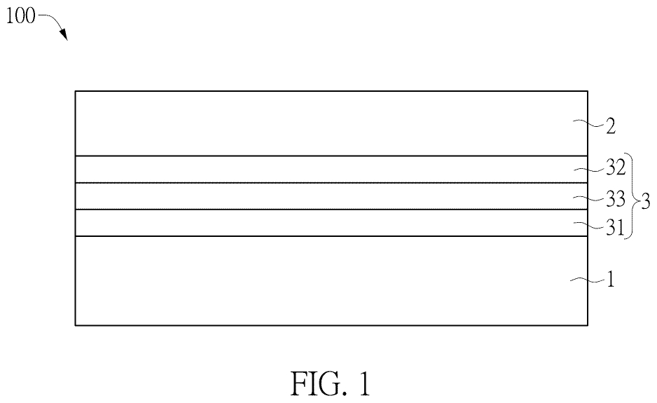

Referring to FIG. 1, FIG. 1 is a schematic view of a composite ceramic substrate according to one embodiment of the present disclosure. An embodiment of the present disclosure provides a composite ceramic substrate 100. The composite ceramic substrate 100 includes a ceramic board 1, a circuit board 2, and a composite adhering structure 3 adhered to the ceramic board 1 and the circuit board 2. The composite ceramic substrate 100 can include any type of the ceramic board 1 and the circuit board 2, and the present disclosure is not limited thereto.

The composite adhering structure 3 includes a first active metal layer 31, a second active metal layer 32, and a solder layer 33. The first active metal layer 31 is adhered to the ceramic board 1, the second active metal layer 32 is adhered to the circuit board 2, and the solder layer 33 is arranged between the first active metal layer 31 and the second active metal layer 32.

In the present embodiment, a thickness of the first active metal layer 31 must be greater than 2 μm and is preferably between 6 μm and 12 μm, a thickness of the second active metal layer 32 must be greater than 6 μm and is preferably between 6 μm and 18 μm, and a thickness of the solder layer 33 must be greater than 6 μm and is preferably between 6 μm and 18 μm, but the present disclosure is not limited thereto.

The first active metal layer 31 includes an active metal material, and the active metal material is selected from the group consisting of a group IV metal, a group V metal, and titanium hydride. The group IV metal is titanium (Ti), zirconium (Zr), or hafnium (Hf), and the group V metal is vanadium (V), niobium (Nb), or tantalum (Ta).

In one embodiment, the active metal material is titanium, and based on a total weight of the first active metal layer 31 being 100 wt %, the first active metal layer includes 100 wt % of titanium. In one embodiment, the active metal material is titanium hydride, and based on the total weight of the first active metal layer 31 being 100 wt %, the first active metal layer 31 includes 100 wt % of titanium hydride. In other words, the first active metal layer 31 can be only made of titanium or titanium hydride, but the present disclosure is not limited thereto.

In one embodiment, the first active metal layer 31 further includes tin and copper, and the active metal material is titanium. Based on the total weight of the first active metal layer 31 being 100 wt %, the first active metal layer 31 includes 27.5 wt % to 47.5 wt % of tin, 50 wt % to 70 wt % of copper, and 0.1 wt % to 5 wt % of titanium. Preferably, based on the total weight of the first active metal layer 31 being 100 wt %, the first active metal layer 31 includes 32.5 wt % to 42.5 wt % of tin, 55 wt % to 65 wt % of copper, and 1 wt % to 4 wt % of titanium. More preferably, based on the total weight of the first active metal layer 31 being 100 wt %, the first active metal layer 31 includes about 37.5 wt % of tin, about 60 wt % of copper, and about 2.5 wt % of titanium.

The second active metal layer 32 is made of titanium or titanium hydride. In other words, the second active metal layer 32 can only include titanium or titanium hydride and does not include other metal components.

The solder layer 33 includes tin and copper. In one embodiment, based on a total weight of the solder layer 33 being 100 wt %, the solder layer 33 includes 65 wt % to 85 wt % of tin and 15 wt % to 35 wt % of copper. Preferably, based on the total weight of the solder layer 33 being 100 wt %, the solder layer 33 includes 70 wt % to 80 wt % of tin and 20 wt % to 30 wt % of copper. More preferably, based on the total weight of the solder layer 33 being 100 wt %, the solder layer 33 includes about 75 wt % of tin and about 25 wt % of copper.

In one embodiment, besides tin and copper, the solder layer 33 further includes titanium. Based on the total weight of the solder layer 33 being 100 wt %, the solder layer 33 includes 27.5 wt % to 47.5 wt % of tin, 50 wt % to 70 wt % of copper, and 0.1 wt % to 5 wt % of titanium. Preferably, based on the total weight of the solder layer 33 being 100 wt %, the solder layer 33 includes 32.5 wt % to 42.5 wt % of tin, 55 wt % to 65 wt % of copper, and 1 wt % to 4 wt % of titanium. More preferably, based on the total weight of the solder layer 33 being 100 wt %, the solder layer 33 includes about 37.5 wt % of tin, about 60 wt % of copper, and about 2.5 wt % of titanium.

In one embodiment, besides tin and copper, the solder layer 33 further includes titanium hydride. Based on the total weight of the solder layer 33 being 100 wt %, the solder layer 33 includes 27.5 wt % to 47.5 wt % of tin, 50 wt % to 70 wt % of copper, and 0.1 wt % to 5 wt % of titanium hydride. Preferably, based on the total weight of the solder layer 33 being 100 wt %, the solder layer 33 includes 32.5 wt % to 42.5 wt % of tin, 55 wt % to 65 wt % of copper, and 1 wt % to 4 wt % of titanium hydride. More preferably, based on the total weight of the solder layer 33 being 100 wt %, the solder layer 33 includes about 37.5 wt % of tin, about 60 wt % of copper, and 2.5 wt % of titanium hydride.

In one embodiment, besides tin and copper, the solder layer 33 further includes silver and titanium. Based on the total weight of the solder layer 33 being 100 wt %, the solder layer 33 includes 12 wt % to 22 wt % of tin, 50 wt % to 60 wt % of copper, 20 wt % to 30 wt % of silver, and 0.1 wt % to 5 wt % of titanium. Preferably, based on the total weight of the solder layer 33 being 100 wt %, the solder layer 33 includes 14.5 wt % to 19.5 wt % of tin, 52.5 wt % to 57.5 wt % of copper, 22.5 wt % to 27.5 wt % of silver, and 1.5 wt % to 4.5 wt % of titanium. More preferably, based on the total weight of the solder layer 33 being 100 wt %, the solder layer 33 includes about 17 wt % of tin, about 55 wt % of copper, about 25 wt % of silver, and about 3 wt % of titanium.

The composite ceramic substrate 100 has a tensile strength of between 100 N/cm and 340 N/cm. Preferably, the tensile strength of the composite ceramic substrate 100 is between 180 N/cm and 340 N/cm. It is worth mentioning that, based on a total weight of the composite adhering structure 3 being 100 wt %, the composite adhering structure 3 includes 10 wt % to 80 wt % of tin, 20 wt % to 50 wt % of titanium, and 0 wt % to 25 wt % of silver. In other words, the composite adhering structure 3 can include no silver or only a small amount of silver overall.

In one embodiment, the first active metal layer 31 includes titanium hydride, the second active metal layer 32 includes tin, copper, and titanium hydride, and the solder layer 33 includes tin, copper, and titanium hydride. Based on the total weight of the first active metal layer 31 being 100 wt %, the first active metal layer 31 can include 100 wt % of titanium hydride, based on the total weight of the second active metal layer 32 being 100 wt %, the second active metal layer 32 can include 20 wt % to 80 wt % of tin, 30 wt % to 70 wt % of copper, and 2 wt % to 20 wt % of titanium hydride, and based on the total weight of the solder layer 33 being 100 wt %, the solder layer 33 can include 20 wt % to 80 wt % of tin, 30 wt % to 70 wt % of copper, and 2 wt % to 20 wt % of titanium hydride.

In the second active metal layer 32, a content of tin can be 20 wt %, 25 wt %, 30 wt %, 35 wt %, 40 wt %, 45 wt %, 50 wt %, 55 wt %, 60 wt %, 65 wt %, 70 wt %, 75 wt %, or 80 wt %. a content of copper can be 30 wt %, 35 wt %, 40 wt %, 45 wt %, 50 wt %, 55 wt %, 60 wt %, 65 wt %, or 70 wt %, and a content of titanium hydride can be 2 wt %, 4 wt %, 6 wt %, 8 wt %, 10 wt %, 12 wt %, 14 wt %, 16 wt %, 18 wt %, or 20 wt %.

In the solder layer 33, a content of tin can be 20 wt %, 25 wt %, 30 wt %, 35 wt %, 40 wt %, 45 wt %, 50 wt %, 55 wt %, 60 wt %, 65 wt %, 70 wt %, 75 wt %, or 80 wt %. a content of copper can be 30 wt %, 35 wt %, 40 wt %, 45 wt %, 50 wt %, 55 wt %, 60 wt %, 65 wt %, or 70 wt %, and a content of titanium hydride can be 2 wt %, 4 wt %, 6 wt %, 8 wt %, 10 wt %, 12 wt %, 14 wt %, 16 wt %, 18 wt %, or 20 wt %.

The composite ceramic substrate 100 can have a tensile strength of greater than 340 N/cm, but the present disclosure is not limited thereto. The composite ceramic substrate 100 can have a tensile strength of between 350 N/cm and 450 N/cm.

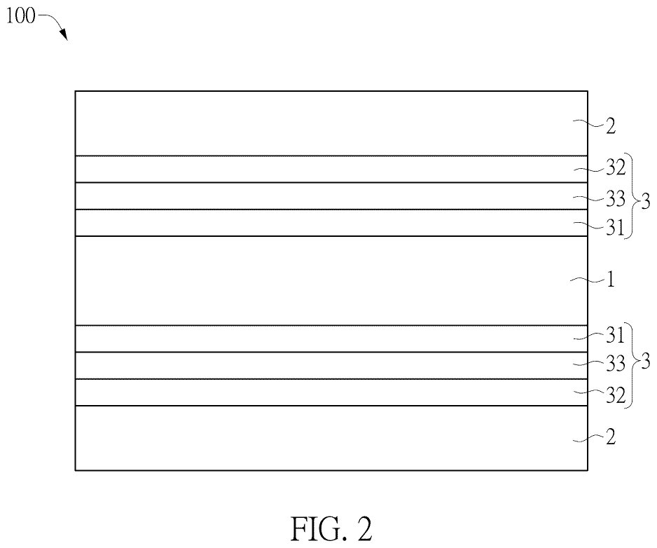

Referring to FIG. 2, FIG. 2 is a schematic view of a composite ceramic substrate according to another embodiment of the present disclosure. In the present embodiment, the composite ceramic substrate 100 can include two circuit boards 2 and two composite adhering structures 3, and the two circuit boards 2 are adhered to two sides of the ceramic board 1 through the two composite adhering structures 3.

### [Method for Producing a Composite Ceramic Substrate]

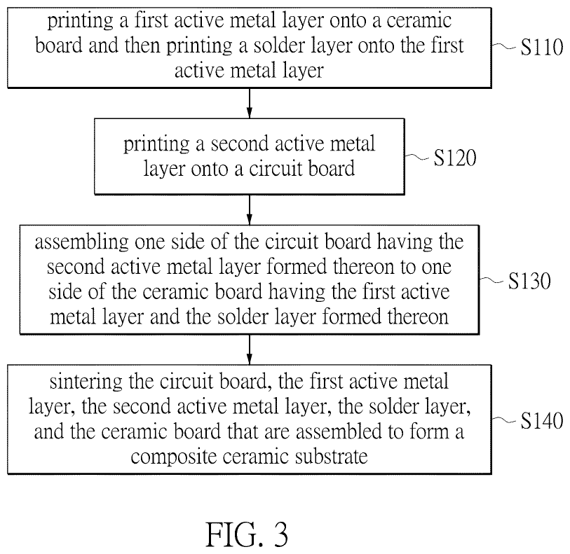

Referring to FIG. 3, FIG. 3 is a flowchart of a method for producing a composite ceramic substrate according to one embodiment of the present disclosure. The present disclosure further provides a method for producing a composite ceramic substrate, the above-mentioned composite ceramic substrate 100 can be obtained by implementing the method for producing the composite ceramic substrate, but the present disclosure is not limited thereto. The method for producing the composite ceramic substrate includes a first printing process S110, a second printing process S120, an assembling process S130, and a sintering process S140. Naturally, the method for producing the composite ceramic substrate can include other processes according to practical requirements, and the present disclosure is not limited thereto.

The first printing process S110 is implemented by printing a first active metal layer 31 onto a ceramic board 1 and then printing a solder layer 33 onto the first active metal layer 31. The first active metal layer 31 includes an active metal material, and the active metal material is selected from the group consisting of a group IV metal, a group V metal, and titanium hydride. The group IV metal is titanium, zirconium, or hafnium, and the group V metal is vanadium, niobium, or tantalum.

In one embodiment, the active metal material is titanium, and based on a total weight of the first active metal layer 31 being 100 wt %, the first active metal layer includes 100 wt % of titanium. In one embodiment, the active metal material is titanium hydride, and based on the total weight of the first active metal layer 31 being 100 wt %, the first active metal layer includes 100 wt % of titanium hydride.

In one embodiment, the first active metal layer 31 further includes tin and copper, and the active metal material is titanium. Based on the total weight of the first active metal layer 31 being 100 wt %, the first active metal layer 31 includes 27.5 wt % to 47.5 wt % of tin, 50 wt % to 70 wt % of copper, and 0.1 wt % to 5 wt % of titanium.

The solder layer 33 includes tin and copper. In one embodiment, based on a total weight of the solder layer 33 being 100 wt %, the solder layer 33 includes 65 wt % to 85 wt % of tin and 15 wt % to 35 wt % of copper.

In one embodiment, besides tin and copper, the solder layer 33 further includes titanium. Based on the total weight of the solder layer 33 being 100 wt %, the solder layer 33 includes 27.5 wt % to 47.5 wt % of tin, 50 wt % to 70 wt % of copper, and 0.1 wt % to 5 wt % of titanium.

In one embodiment, besides tin and copper, the solder layer 33 further includes titanium hydride. Based on the total weight of the solder layer 33 being 100 wt %, the solder layer 33 includes 27.5 wt % to 47.5 wt % of tin, 50 wt % to 70 wt % of copper, and 0.1 wt % to 5 wt % of titanium hydride.

In one embodiment, besides tin and copper, the solder layer 33 further includes silver and titanium. Based on the total weight of the solder layer 33 being 100 wt %, the solder layer 33 includes 12 wt % to 22 wt % of tin, 50 wt % to 60 wt % of copper, 20 wt % to 30 wt % of silver, and 0.1 wt % to 5 wt % of titanium.

In one embodiment, the first active metal layer 31 includes titanium hydride, and the solder layer 33 includes tin, copper, and titanium hydride. The first active metal layer 31 can include 100 wt % of titanium hydride, and based on the total weight of the solder layer 33 being 100 wt %, the solder layer 33 can include 20 wt % to 80 wt % of tin, 30 wt % to 70 wt % of copper, and 2 wt % to 20 wt % of titanium hydride.

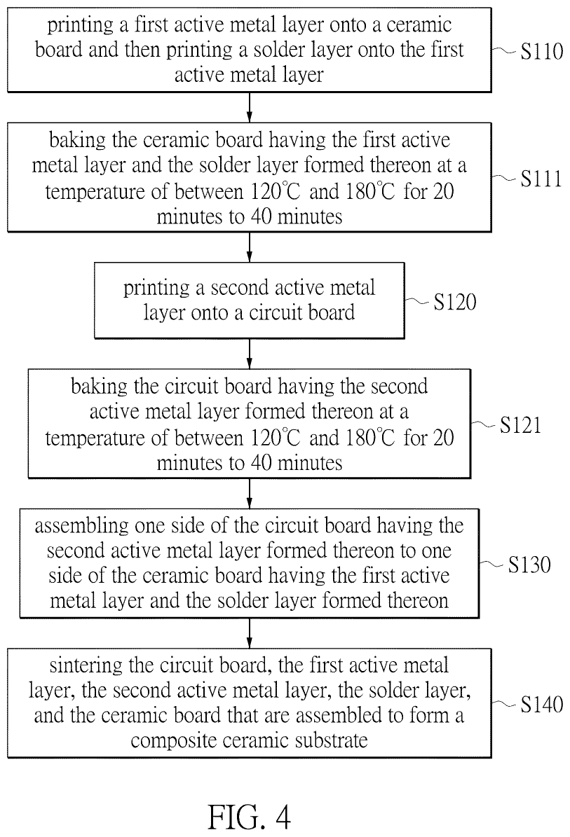

Referring to FIG. 4, FIG. 4 is a flowchart of a method for producing a composite ceramic substrate according to another embodiment of the present disclosure. After the first printing process S110, the method for producing the composite ceramic substrate can further include a first baking process S111 implemented by baking the ceramic board 1 having the first active metal layer 31 and the solder layer 33 formed thereon at a temperature of between 120° C. and 180° C. for 20 minutes to 40 minutes.

The second printing process S120 is implemented by printing a second active metal layer 32 onto a circuit board 2. The second active metal layer 32 is made of titanium or titanium hydride.

In one embodiment, the second active metal layer 32 includes tin, copper, and titanium hydride. Base one the total weight of the second active metal layer 32 being 100 wt %, the second active metal layer 32 can include 20 wt % to 80 wt % of tin, 30 wt % to 70 wt % of copper, and 2 wt % to 20 wt % of titanium hydride.

Referring to FIG. 4, after the second printing process S120, the method for producing the composite ceramic substrate can further include a second baking process S121 implemented by baking the circuit board 2 having the second active metal layer 32 formed thereon at a temperature of between 120° C. and 180° C. for 20 minutes to 40 minutes.

The assembling process S130 is implemented by assembling one side of the circuit board 2 having the second active metal layer 32 formed thereon to one side of the ceramic board 1 having the first active metal layer 31 and the solder layer 33 formed thereon.

The sintering process S140 is implemented by sintering the circuit board 2, the first active metal layer 31, the second active metal layer 32, the solder layer 33, and the ceramic board 1 that are assembled to form a composite ceramic substrate 100. In the sintering process S140 of one embodiment, the circuit board 2, the first active metal layer 31, the second active metal layer 32, the solder layer 33, and the ceramic board 1 that are assembled are sintered at a temperature of between 800° C. and 1,000° C. and under a pressure of between 5×10⁻⁶ torr and 5×10⁻⁴ torr for 20 minutes to 50 minutes. Preferably, in the sintering process S140, the circuit board 2, the first active metal layer 31, the second active metal layer 32, the solder layer 33, and the ceramic board 1 that are assembled are sintered under a pressure of between 4×10⁻⁶ torr and 6×10⁻⁴ torr.

In the present embodiment, a thickness of the first active metal layer 31 is between 3 μm and 15 μm, a thickness of the second active metal layer 32 is between 3 μm and 9 μm, and a thickness of the solder layer 33 is between 3 μm and 15 μm, but the present disclosure is not limited thereto.

In one embodiment, the thickness of the first active metal layer 31 can be between 6 μm and 12 μm, the thickness of the second active metal layer 32 can be between 6 μm and 18 μm, and the thickness of the solder layer 33 can be between 6 μm and 18 μm. The composite ceramic substrate 100 can have a tensile strength of greater than 340 N/cm, but the present disclosure is not limited thereto.

In addition, after the sintering process S140 of one embodiment, the first active metal layer 31, the solder layer 33, and the second active metal layer 32 of the composite adhering structure 3 can gradually form an active metal layer, a connection structure layer, and a eutectic main structure layer, and the connection structure is located between the active metal layer and the eutectic main structure layer. The active metal layer is mainly formed of titanium, the connection structure layer is formed of tin as well as silver and copper that are dispersed in tin, and the eutectic main structure layer is formed of tin and a eutectic structure dispersed in tin that is formed by copper and titanium, but the present disclosure is not limited thereto.

### Experimental Results

Hereinafter, a more detailed description will be provided with reference to Exemplary Examples 1 to 8 and Comparative Examples 1 and 2. However, the following Exemplary Examples are only used to aid in understanding of the present disclosure, and are not to be construed as limiting the scope of the present disclosure.

Exemplary Example 1: the first active metal layer includes 37.5 wt % of tin, 60 wt % of copper, and 2.5 wt % of titanium, the solder layer includes 37.5 wt % of tin, 60 wt % of copper, and 2.5 wt % of titanium, and the second active metal layer includes 100 wt % of titanium hydride.

Exemplary Example 2: the first active metal layer includes 37.5 wt % of tin, 60 wt % of copper, and 2.5 wt % of titanium, the solder layer includes 17 wt % of tin, 55 wt % of copper, 25 wt % of silver, and 3 wt % of titanium, and the second active metal layer includes 100 wt % of titanium hydride.

Exemplary Example 3: the first active metal layer includes 100 wt % of titanium, the solder layer includes 37.5 wt % of tin, 60 wt % of copper, and 2.5 wt % of titanium, and the second active metal layer includes 100 wt % of titanium.

Exemplary Example 4: the first active metal layer includes 100 wt % of titanium hydride, the solder layer includes 37.5 wt % of tin, 60 wt % of copper, and 2.5 wt % of titanium hydride, and the second active metal layer includes 100 wt % of titanium hydride.

Exemplary Example 5: the first active metal layer includes 100 wt % of titanium hydride, the solder layer includes 17 wt % of tin, 55 wt % of copper, 25 wt % of silver, and 3 wt % of titanium, and the second active metal layer includes 100 wt % of titanium hydride.

Exemplary Example 6: the first active metal layer includes 100 wt % of titanium hydride, the solder layer includes 75 wt % of tin and 25 wt % of copper, and the second active metal layer includes 100 wt % of titanium hydride.

Exemplary Example 7: the first active metal layer includes 100 wt % of titanium hydride, the solder layer includes 26 wt % of tin, 70 wt % of copper, and 4 wt % of titanium hydride, and the second active metal layer includes 26 wt % of tin, 70 wt % of copper, and 4 wt % of titanium hydride. The thickness of the first active metal layer is 6 μm, the thickness of the solder layer is 12 μm, and the thickness of the second active metal layer is 12 μm.

Exemplary Example 8: the first active metal layer includes 100 wt % of titanium hydride, the solder layer includes 48 wt % of tin, 48 wt % of copper, and 4 wt % of titanium hydride, and the second active metal layer includes 48 wt % of tin, 48 wt % of copper, and 4 wt % of titanium hydride.

Comparative Example 1: the first active metal layer includes 73 wt % of silver, 22 wt % of copper, and 5 wt % of titanium, and the second active metal layer includes 73 wt % of silver, 22 wt % of copper, and 5 wt % of titanium.

Comparative Example 2: the first active metal layer includes 100 wt % of titanium hydride, the solder layer includes 26 wt % of tin, 70 wt % of copper, and 4 wt % of titanium hydride, and the second active metal layer includes 26 wt % of tin, 70 wt % of copper, and 4 wt % of titanium hydride. The thickness of the first active metal layer is 6 μm, the thickness of the solder layer is 12 μm, and the thickness of the second active metal layer is 18 μm.

For the composite ceramic substrate of each of Exemplary Examples 1 to 8 and Comparative Examples 1 and 2, the components of the composite adhering structure, thickness, tensile strength, and uniformity are listed in Table 1 below. The relevant test methods are also described as follows.

Tensile strength is measured through 90-degree peel test according to IPC-TM 650 Test methods manual No. 2.4.9 “Peel Strength, Flexible Dielectric Materials.

Uniformity is observed by using an ultrasound scanning microscope developed by Sonoscan company.

| | Exemplary | Exemplary | Exemplary | Exemplary |
|---|---|---|---|---|
| Item | Example 1 | Example 2 | Example 3 | Example 4 |
| Material of first | Sn—Cu—Ti | Sn—Cu—Ti | Ti | TiH₂ |
| active metal | | | | |
| layer | | | | |
| Content of each | 37.5-60-2.5 | 37.5-60-2.5 | 100 | 100 |
| component in | | | | |
| first active | | | | |
| metal layer | | | | |
| (wt %) | | | | |
| Thickness of | 12 | 12 | 6 | 6 |
| first active | | | | |
| metal layer | | | | |
| (μm) | | | | |
| Material of | Sn—Cu—Ti | Sn—Cu—Ag—Ti | Sn—Cu—Ti | Sn—Cu—TiH₂ |
| solder layer | | | | |
| Content of each | 37.5-60-2.5 | 17-55-25-3 | 37.5-60-2.5 | 37.5-60-2.5 |
| component in | | | | |
| solder layer | | | | |
| (wt %) | | | | |
| Thickness of | 12 | 12 | 6 | 6 |
| solder layer | | | | |
| (μm) | | | | |
| Material of | TiH₂ | TiH₂ | Ti | TiH₂ |
| second active | | | | |
| metal layer | | | | |
| Content of each | 100 | 100 | 100 | 100 |
| component in | | | | |
| second active | | | | |
| metal layer | | | | |
| (wt %) | | | | |
| Thickness of | 6 | 6 | 6 | 6 |
| second active | | | | |
| metal layer | | | | |
| (μm) | | | | |
| Thickness of | 2 | 2 | 5 | 5 |
| connection | | | | |
| structure layer | | | | |
| (μm) | | | | |
| Tensile strength | 100 | 150 | 180 | 200 |
| (N/cm) | | | | |
| Uniformity | good | good | excellent | excellent |

| | Exemplary | Exemplary | Comparative |
|---|---|---|---|
| Item | Example 5 | Example 6 | Example 1 |
| Material of first | TiH₂ | TiH₂ | Ag—Cu—Ti |
| active metal layer | | | |
| Content of each | 100 | 100 | 73—22—5 |
| component in first | | | |
| active metal layer | | | |
| (wt %) | | | |
| Thickness of first | 6 | 6 | 12 |
| active metal layer | | | |
| (μm) | | | |
| Material of solder | Sn—Cu—Ag—Ti | Sn—Cu | none |
| layer | | | |
| Content of each | 17-55-25-3 | 75-25 | none |
| component in | | | |
| solder layer (wt %) | | | |
| Thickness of | 12 | 12 | none |
| solder layer (μm) | | | |
| Material of | TiH₂ | TiH₂ | Ag—Cu—Ti |
| second active | | | |
| metal layer | | | |
| Content of each | 100 | 100 | 73-22-5 |
| component in | | | |
| second active | | | |
| metal layer (wt %) | | | |
| Thickness of | 6 | 6 | 12 |
| second active | | | |
| metal layer (μm) | | | |
| Thickness of | 5 | 5 | none |
| connection | | | |
| structure layer | | | |
| (μm) | | | |
| Tensile strength | 280 | 340 | 200 |
| (N/cm) | | | |
| Uniformity | excellent | excellent | normal |

### [Discussion of Test Results]

As shown in Exemplary Example 6, since the first active metal layer and the second active metal layer are made of titanium hydride and the solder layer is made of tin and copper, the composite ceramic substrate has an excellent tensile strength and an excellent uniformity. As shown in Exemplary Examples 1 to 5, the first active metal layer can be also made of titanium, or can include tin and copper, and the second active metal layer can be also made of titanium. In addition, the solder layer can be only made of tin and copper, or can include titanium or titanium hydride. As shown in Exemplary Examples 7 and 8, since the first active metal layer includes titanium hydride and the solder layer and the second active metal layer include tin, copper, and titanium hydride, the composite ceramic substrate can have relatively strong tensile strength and excellent uniformity. As shown in Comparative Example 1, high content of silver causes insufficient tensile strength and poor uniformity. As shown in Comparative Example 2, the thickness of the second active metal layer is excessive, causing an overflow problem of the composite ceramic substrate.

### Beneficial Effects of the Embodiment

In conclusion, in the composite ceramic substrate and method for producing the same, by virtue of “the first active metal layer including titanium hydride, the solder layer including tin, copper, and titanium hydride, and the second active metal layer including tin, copper, and titanium hydride,” the issues involving the probability of electromigration and the high cost due to the high content of silver used in a conventional method for producing a ceramic substrate can be effectively improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A composite ceramic substrate, comprising:
a ceramic board;
a circuit board; and
a composite adhering structure adhered to the ceramic board and the circuit board, wherein the composite adhering structure includes:
a first active metal layer adhered to the ceramic board, wherein the first active metal layer includes titanium hydride;
a second active metal layer adhered to the circuit board, wherein the second active metal layer includes tin, copper, and titanium hydride; and
a solder layer arranged between the first active metal layer and the second active metal layer, wherein the solder layer includes tin, copper, and titanium hydride.

2. The composite ceramic substrate according to claim 1, wherein, based on a total weight of the second active metal layer being 100 wt %, the second active metal layer includes 20 wt % to 80 wt % of tin, 30 wt % to 70 wt % of copper, and 2 wt % to 20 wt % of titanium hydride.

3. The composite ceramic substrate according to claim 1, wherein, based on a total weight of the solder layer being 100 wt %, the solder layer includes 20 wt % to 80 wt % of tin, 30 wt % to 70 wt % of copper, and 2 wt % to 20 wt % of titanium hydride.

4. The composite ceramic substrate according to claim 1, wherein, based on a total weight of the first active metal layer being 100 wt %, the first active metal layer includes 100 wt % of titanium hydride.

5. The composite ceramic substrate according to claim 1, wherein a thickness of the first active metal layer is between 6 μm and 12 μm, a thickness of the second metal layer is between 6 μm and 18 μm, and a thickness of the solder layer is between 6 μm and 18 μm.

6. The composite ceramic substrate according to claim 1, wherein the composite ceramic substrate has a tensile strength of greater than 340 N/cm.

7. A method for producing a composite ceramic substrate, comprising:
a first printing process implemented by printing a first active metal layer onto a ceramic board and then printing a solder layer onto the first active metal layer, wherein the first active metal layer includes titanium hydride, and wherein the solder layer includes tin, copper, and titanium hydride;
a second printing process implemented by printing a second active metal layer onto a circuit board, wherein the second active metal layer includes tin, copper, and titanium hydride;
an assembling process implemented by assembling one side of the circuit board having the second active metal layer formed thereon to one side of the ceramic board having the first active metal layer and the solder layer formed thereon; and
a sintering process implemented by sintering the circuit board, the first active metal layer, the second active metal layer, the solder layer, and the ceramic board that are assembled to form a composite ceramic substrate.

8. The method according to claim 7, wherein, based on a total weight of the second active metal layer being 100 wt %, the second active metal layer includes 20 wt % to 80 wt % of tin, 30 wt % to 70 wt % of copper, and 2 wt % to 20 wt % of titanium hydride.

9. The method according to claim 7, wherein, based on a total weight of the solder layer being 100 wt %, the solder layer includes 20 wt % to 80 wt % of tin, 30 wt % to 70 wt % of copper, and 2 wt % to 20 wt % of titanium hydride.

10. The method according to claim 7, wherein, based on a total weight of the first active metal layer being 100 wt %, the first active metal layer includes 100 wt % of titanium hydride.

11. The method according to claim 7, wherein a thickness of the first active metal layer is between 6 μm and 12 μm, a thickness of the second metal layer is between 6 μm and 18 μm, and a thickness of the solder layer is between 6 μm and 18 μm.

12. The method according to claim 7, wherein the composite ceramic substrate has a tensile strength of greater than 340 N/cm.
